(19) United States
(12) Patent Application Publication
(10) Pub. No.: US 2014/0376605 A1
(43) Pub. Date: Dec. 25, 2014

(54) APPARATUS AND METHOD FOR COMPRESSING AND DECOMPRESSING DATA

(71) Applicant: Electronics and Telecommunications Research Institute, Daejeon (KR)

(72) Inventors: Seung Hwan KIM, Daejeon (KR); Eui Suk JUNG, Daejeon (KR); Sang Soo LEE, Daejeon (KR); Yong Yuk WON, Paju-si Gyeonggi-do (KR); Sang Min YOON, Seoul (KR)

(21) Appl. No.: 14/314,440

(22) Filed: Jun. 25, 2014

(30) Foreign Application Priority Data
Jun. 25, 2013 (KR) 10-2013-0073331
May 8, 2014 (KR) 10-2014-0054965

(51) Int. Cl. H03M 7/30

(52) U.S. Cl. CPC H03M 7/3062; H03M 7/6005
USPC 375/240

(57) ABSTRACT

Disclosed are methods and apparatuses for compressing and decompressing data at a sample rate lower than a Nyquist sampling rate for the data. The data compression apparatus comprises a domain converting part performing a domain conversion on input data to generate domain-converted input data, and a data compression part generating compressed data by down-sampling the domain-converted input data at a sampling rate lower than a Nyquist sampling rate. Therefore, data to be transmitted can be compressed in a transmitting end by sampling the data at a sampling rate lower than a Nyquist sampling rate, and then the data can be reproduced in a receiving end. Therefore, a higher compression ratio can be achieved as compared with that of conventional technologies.

### CLAIM FOR PRIORITY

This application claims priorities to Korean Patent Application No. 10-2013-0073331 filed on Jun. 25, 2013 and No. 10-2014-0054965 filed on May 8, 2014 in the Korean Intellectual Property Office (KIPO), the entire contents of which are hereby incorporated by references.

### BACKGROUND

1. Technical Field

Example embodiments of the present invention relate to a data transmission interface for wired or wireless networks, and more specifically to an apparatus and a method for compressing data at a sampling rate lower than a Nyquist sampling rate and decompressing the data.

2. Related Art

An Industry Specification Group (ISG) under an European Telecommunications Standards Institute (ETSI) as an European standard organization is progressing standardization on an Open Radio equipment Interface (ORI) defining interfaces between a Radio Equipment Control (REC) and a Radio Equipment (RE) of the conventional radio base station in order to cope with migration of a next generation mobile communication radio network structure to a small and distributed base station system. The ORI is based on the existing Common Public Radio Interface (CPRI) standard, a standard for resolving problems of incompatibility between apparatuses, and it is progressing standardization on IQ data compression.

Currently, communication network operators and equipment vendors require more separated type base stations in order to implement a system such as an LTE-TDD, a Mobile Hotspot Network (MHN), etc. Also, since several tens of Gbps data rate surpassing 9.8 Gbps data rate which is currently being provided based on the existing CPRI standard is demanded, efforts for reducing costs for system deployments and maintenances by using data compression techniques are going on.

Alcatel Lucent (ALU) has proposed a compression algorithm based on the CPRI which is a transmission specification for separated-type base stations.

FIG. 1 is a flow chart to explain a technique for compressing IQ data which has been proposed by ALU.

Referring to FIG. 1, in a first step S110, signals are sampled and filtered. For example, a 10 MHz LTE signal may be sampled using 15.36 MHz clocks in order to meet the CPRI specification (S111). A low pass filtering procedure (S112) for obtaining only two-thirds of total signal and decimating the rest of the total signal is performed by using frequency characteristics that only few effective data components exist over 10.24 MHz. A second step S120 may be referred to as a block scaling step. For example, in the step S120, only 11 bits may be obtained as effective bits from IQ data configured with 15 bits (S121), and calculated scaling factor may be applied (S122, S123) to the obtained 11 bits. In this case, it is possible to transmit only three-fourths of original data for maintaining Error Vector Magnitude (EVM) not higher than 1%. Therefore, ALU suggests 50% as a resultant compression ratio after performing the above two steps.

The disclosed technique of ALU has advantages of easiness in system implementation and restricted delays in compression and decompression. However, it has a low compression ratio.

Meanwhile, a registered patent U.S. Pat. No. 8,331,461 of Integrated Device Technology (IDT), “Compression of baseband transceiver system radio units”, provides a compression apparatus which can be used for a mobile communication system.

According to the patent, only effective bits smaller than half of IQ data configured with 20 bits or less are transmitted to a receiving end and reproduced in the receiving end. Specifically, a total phase of 360 degrees is divided into sections having 10 degree interval, 60 degree interval, 90 degree interval, 120 degree interval, and 180 degree interval. A section is selected for each data in consideration of intensity and phase of each data so that the selected section has the smallest difference from the actual position of the corresponding data. Then, the reference number indicating the selected section and information about the difference between the actual phase of each data and the selected section may be transmitted to the receiving end. In this case, even though only a portion of total bits constituting original signal are transmitted, the original signal can be reproduced with a compression ratio higher than 50%. However, the above-described technique has a shortcoming that it should have a loss corresponding to an acceptable error.

### SUMMARY

Accordingly, example embodiments of the present invention are provided to substantially obviate one or more problems due to limitations and disadvantages of the related art.

Example embodiments of the present invention provide a data compression apparatus to compress data with an enhanced compression ratio for a wired or wireless network data transmission interface.

Example embodiments of the present invention also provide a data decompression apparatus to decompress data compressed with an enhanced compression ratio for a wired or wireless network data transmission interface.

Example embodiments of the present invention also provide a network system, in which data is compressed with an enhanced compression ratio and the compressed data is decompressed, for a wired or wireless network data transmission interface.

In some example embodiments, a data compressing apparatus for a network interface may comprise a domain converting part performing a domain conversion on input data to generate domain-converted input data; and a data compression part generating compressed data by down-sampling the domain-converted input data at a sampling rate lower than a Nyquist sampling rate.

Here, the domain converting part performs the domain conversion on the input data by using one of a Fast Fourier Transform (FFT), a Discrete Cosine Transform (DCT), and a Discrete Wavelet Transform (DWT).

Here, the domain converting part calculates a sparsity value about the domain-converted input data.

Here, the data compression part down-samples the domain-converted input data by using one of a low pass filtering, a random sampling, and a nonlinear vector function.

Here, the data compression part processes the domain-converted input data by representing the domain-converted input data in vector format. Also, the data compression part multiplies the domain-converted input data by a down-sampling vector which can sample the domain-converted input data at a sampling rate lower than a Nyquist sampling rate to generate the compressed data.

In other example embodiments, a data decompression apparatus for a network interface may comprise a channel equalization part receiving compressed data generated by down-sampling at a sampling rate lower than a Nyquist sampling rate, equalizing the compressed data in order to compensate channel distortion, and generating equalized compressed data; a data decompression part generating domain-converted decompressed data by up-sampling the equalized compressed data; and a domain inverse-converting part performing an inverse-domain conversion on the domain-converted decompressed data to generate decompressed data.

Here, the data decompression part generates the domain-converted decompressed data by deriving an up-sampling vector which can up-sample the equalized compressed data and multiplying the equalized compressed data by the up-sampling vector.

Here, the up-sampling vector is derived using an L1 minimization technique.

Here, the domain inverse-converting part performs the domain inverse-conversion corresponding to a domain-conversion by using one of a Fast Fourier Transform (FFT), a Discrete Cosine Transform (DCT), and a Discrete Wavelet Transform (DWT).

In other example embodiments, a network system performing data compression and decompression may comprise a transmitting apparatus performing a domain conversion on input data to generate domain-converted input data, generating compressed data by down-sampling the domain-converted input data at a sampling rate lower than a Nyquist sampling rate, and transmitting the compressed data; and a receiving apparatus receiving the compressed data, equalizing the compressed data to generate equalized compressed data, generating domain-converted decompressed data by up-sampling the equalized compressed data; and performing an inverse-domain conversion on the domain-converted decompressed data to generate decompressed data.

Here, the transmitting apparatus down-samples the domain-converted input data by using one of a low pass filtering, a random sampling, and a nonlinear vector function.

Here, the transmitting apparatus processes the domain-converted input data by representing the domain-converted input data in vector format, and multiplies the domain-converted input data by a down-sampling vector which can sample the domain-converted input data at a sampling rate lower than a Nyquist sampling rate to generate the compressed data.

Here, the receiving apparatus generates the domain-converted decompressed data by deriving an up-sampling vector which can up-sample the equalized compressed data and multiplying the equalized compressed data by the up-sampling vector. Also, the up-sampling vector is derived using an L1 minimization technique.

According to the above-described data compression apparatus and data decompression apparatus, data to be transmitted can be compressed in a transmitting end by sampling the data at a sampling rate lower than a Nyquist sampling rate, and then the data can be reproduced in a receiving end. Therefore, a higher compression ratio can be achieved as compared with that of conventional technologies.

Also, embodiments of the present invention may reduce a Capital Expenditure (CAPEX) and an Operating Expenditure (OPEX) consumed for additional investments on network systems coping with explosive increases of wireless traffics.

### BRIEF DESCRIPTION OF DRAWINGS

Example embodiments of the present invention will become more apparent by describing in detail example embodiments of the present invention with reference to the accompanying drawings, in which:

FIG. 1 is a flow chart to explain a technique for compressing IQ data which has been proposed by ALU;

FIG. 2 is a block diagram to explain a data compression apparatus according to an example embodiment of the present invention;

FIG. 3 is a block diagram to explain a data decompression apparatus according to an example embodiment of the present invention; and

FIG. 4 is a conceptual diagram to explain a network system according to an example embodiment of the present invention.

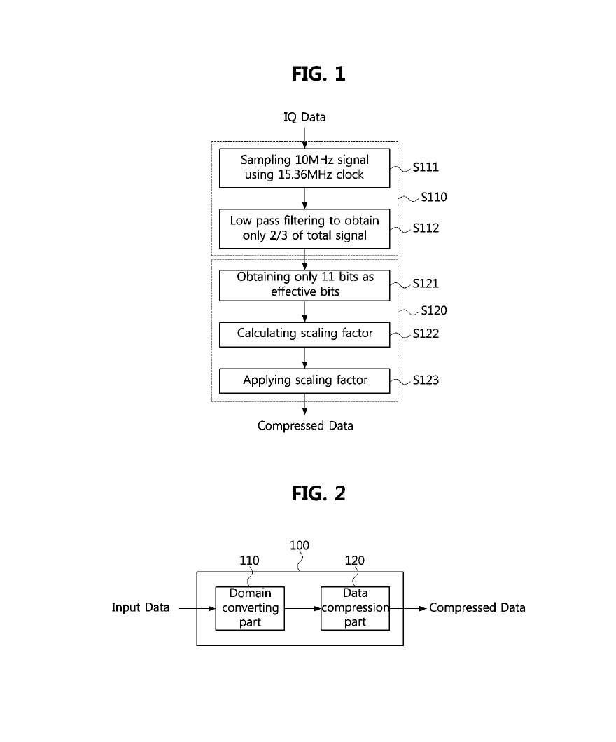

### DESCRIPTION OF EXAMPLE EMBODIMENTS

Example embodiments of the present invention are disclosed herein. However, specific structural and functional detail disclosed herein are merely representative for purposes of describing example embodiments of the present invention, however, example embodiments of the present invention may be embodied in many alternate forms and should not be construed as limited to example embodiments of the present invention set forth herein. Accordingly, while tie invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that when an element is referred to as being “on” or “below” another element, it can be directly on another element or intervening elements may be present.

It will be understood that, although the terms first, second, A, B, etc. may be used herein to describe various elements, these elements should not be limited by these terms. These terms are only used to distinguish one element from another. For example, a first element could be termed a second element, and similarly, a second element could be termed a first element, without departing from the scope of the present invention. As used here, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The terminology used herein is for the purpose of describing particular embodiments only and is not intended to be limiting of the invention. As used herein, the singular forms are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present invention will be described in detail with reference to the appended drawings. In the following description, for easy understanding, like numbers refer to like elements throughout the description of the figures regardless of number of the figures.

FIG. 2 is a block diagram to explain a data compression apparatus according to an example embodiment of the present invention.

Referring to FIG. 2, the data compression apparatus 100 according to an embodiment of the present invention may comprise a domain conversion part 110 and a data compression part 120. Also, the apparatus 100 may be prepared in a transmitting apparatus (or, a transmitting part of an apparatus) of a network system 300.

The domain conversion part 110 may perform a domain conversion on received input data. Here, the input data may mean original data before data compression, and signals in binary form used in the wired or wireless network system 300. For example, the input data may be IQ data for a mobile communication system based Long Term Evolution (LTE) signals, and represented as binary data comprising about 15 bits. Here, the IQ data may mean in-phase and quadrature-phase modulated data.

Also, the input data may mean whole part or a specific field of a transmission frame defined in various transmission standards.

Specifically, the domain conversion part 110 may form a domain conversion on the input data by using one of a Fast Fourier Transform (FFT), a Discrete Cosine Transform (DCT), and a Discrete Wavelet Transform (DWT).

The FFT is a transformation technique which converts time-domain data into frequency-domain data, and enables selection of effective frequency components which cannot be observed in time domain.

The DCT represents given data as summation of multiple cosine functions having different frequencies. Since multimedia data have an ‘energy concentration effect’ that most of energy components are concentrated in low frequency components, the DCT technique may generally be used for a lossy compression. For example, a Joint Photography Experts Group (JPEG) image compression, a Moving Picture Experts Group (MPEG) video compression, etc. use the DCT technique as their lossy compression techniques.

The DWT is similar to the FFT technique. However, since it converts position components of a time-domain signal as well as frequency components of the signal, it has a loss less than that of the FFT, and has higher conversion efficiency.

Also, the domain conversion part 110 may calculate a sparsity value for domain-converted input data. Here, the sparsity value may represent an occupation ratio of data having values of zero or near-zero among whole data, and may be calculated according to a below equation 1.

$$Sparsity ( \% ) = \frac{( \begin{matrix}the number of data having a vaule 0 near 0 in domain - \\ converted data\end{matrix} )}{( the number of whole data in domain - converted data )} \times 100 \qquad [ Equation 1 ]$$

The conventional information/communication system has been progressed as focused upon a digital system designed based on sampling theories of Shannon and Nyquist. Generally, a digital system starts its processing by converting analog signal into digital signal.

In other words, after analog signals such as photo signals and voice signals are converted into digital signals, signals may be represented not in real numbers but in integer numbers. Therefore, they may be stored and reproduced by a computer operating based on a binary scheme, so that they may also be transmitted via a digital communication network without errors.

Since the procedure for converting analog signals into digital signals is performed by an Analog-to-Digital (ADC) converter, technologies for ADC are essential elements for implementing a digital system.

Such the ADC has been implemented based on a Nyquist-Shannon sampling theory. A sampling rate in the ADC is proportional to amount of information which can be represented. More specifically, if signal is sampled at a sample rate double the highest frequency of the signal, the sampled signal may be reproduced into the accurate analog signal again. This is the Nyquist-Shannon sampling theory which has been utilized as a basic theory for constructing a digital system.

As compared with the above case, the data compression part 120 according to the present invention may generate compressed data by down-sampling domain-converted input data from the domain conversion part 110 at a sampling rate lower than a Nyquist sampling rate for the input data. Here, since the Nyquist sampling rate means a sampling rate double the highest frequency of frequency components of the input data, the data compression part 120 may be explained to generate the compressed data by sampling the domain-converted input data at a sampling rate lower than twice of the highest frequency of the input data.

Specifically, the data compression part 120 may down-samples the domain-converted input data by using one of a low pass filter, a random sampling, and a nonlinear vector function.

The data compression part 120 may process the domain-converted input data by representing the domain-converted input data in a vector format. That is, the data compression part 120 may multiply the domain-converted input data by a down-sampling vector which can sample the domain-converted input data at a sampling rate lower than a Nyquist sampling rate to generate the compressed data.

For example, if size of the domain-converted input data is supposed to be N, the domain-converted input data may be represented as 1×N in vector format. Also, the down-sampling vector which can sample the domain-converted input data at a sampling rate lower than a Nyquist sampling rate may be represented as N×M. Here, M is smaller than N. That is, M<N.

A data compression procedure performed in the data compression part 120 may be represented as a below equation 2.

compressed data(1×M)=(domain−converted input data(1×N))×(down−sampling vector(N×M)) [Equation 2]

According to the equation 2, the compressed data having a size of 1×M may be derived from multiplication of the domain-converted input data (1×N) and the down-sampling vector (N×M).

Also, a compression ratio according to the equation 2 may be represented as a below equation 3.

$$compression ratio ( \% ) = 1 - \frac{compressed data ( 1 \times M )}{domain - converted input date ( 1 \times N )} \times 100 \qquad [ Equation 3 ]$$

For example, when the domain-converted input data has a size of 1×10 and the down-sampling vector has a size of 10×5, the compressed data may have a size of 1×5, and so the compression ratio may be 50%. Also, in case of LTE signal, if compressed data has a length of 7.5 bits for input data having a length of 15 bits, the resultant compression ratio may be 50%.

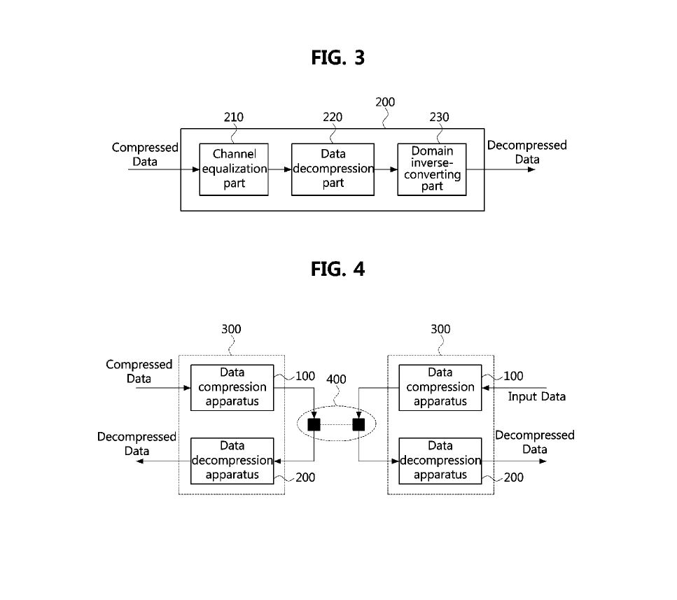

FIG. 3 is a block diagram to explain a data decompression apparatus according to an example embodiment of the present invention.

Referring to FIG. 3, the data decompression part 200 may comprise a channel equalization part 210, a data decompression part 220, and a domain inverse-converting part 230. Also, the apparatus 200 may be prepared in a receiving apparatus (or, a receiving part of an apparatus) of a network system 300.

The channel equalization part 210 may receive compressed data generated by down-sampling at a sampling rate lower than a Nyquist sampling rate, and equalize the compressed data in order to compensate channel distortion. Here, the channel equalization part 210 may receive the compressed data via a wireless or wired medium 400.

The data decompression part 220 may generate domain-converted decompressed data by up-sampling the equalized compressed data.

Specifically, the data decompression part 220 may generate the domain-converted decompressed data by deriving an up-sampling vector which can up-sample the equalized compressed data and multiplying the equalized compressed data by the up-sampling vector. Here, the up-sampling vector may be derived as an inverse matrix of the down-sampling vector by using an L1 minimization technique.

The domain-converted decompressed data may have a sparsity value identical to the sparsity value for the domain-converted input data before data compression in the above-described data compression apparatus 100. Therefore, the data decompression apparatus 200 according to an embodiment of the present invention can reproduce the original data within an acceptable error range.

The domain inverse-converting part may perform an inverse-domain conversion on the domain-converted decompressed data to generate decompressed data. That is, the domain inverse-converting part 230 may perform the inverse-domain conversion corresponding to the domain conversion performed using one of a FFT, a DCT, and a DWT.

The above-described data compression apparatus 100 and data decompression part 200 may be applied to not only an environment using separated type base stations but also various applications such as an access network, a backbone network, a system using time division, frequency division, wave-length division, code division, and OFDMA, network entities such as routers, switches, and terminals. Also, embodiments of the present invention may be widely applied to various communication systems, which require compression of data to be transmitted through a satellite communication, a fixed wireless communication, and a mobile communication network and decompression of the data.

FIG. 4 is a conceptual diagram to explain a network system according to an example embodiment of the present invention.

Referring to FIG. 4, the network system 400 according to an embodiment of the present invention may comprise a transmitting apparatus and a receiving apparatus.

Here, the transmitting apparatus may be the data compression apparatus 100 illustrated in FIG. 2, or include the data compression apparatus 100. Also, the receiving apparatus may be the data decompression apparatus 200 illustrated in FIG. 3, or include the data decompression apparatus 200.

Also, the transmitting apparatus and the receiving apparatus may be connected through a various wired or wireless medium 400. The wired or wireless medium may include a wired medium such as optical cable, coaxial cable, etc. and a wireless medium such as radio wave, ground microwave, etc.

When data is converted from time domain to frequency domain, most of the converted data may have zero values and only few of the converted data have non-zero values. The network system 300 according to an embodiment of the present invention is based on the above theory. Accordingly, only small number of linear measurements are needed for reproducing the original data.

The transmitting apparatus may perform a domain-conversion on input data, generate compressed data by down-sampling the domain-converted input data at a sampling rate lower than a Nyquist sampling rate, and transmit the compressed data.

The transmitting apparatus may down-sample the domain-converted compressed data by one of a low pass filtering, a random sampling, and a nonlinear vector function.

Specifically, the transmitting apparatus may process the domain-converted input data by representing the domain-converted input data in a vector format. Also, the transmitting apparatus may multiply the domain-converted input data by a down-sampling vector which can sample the domain-converted input data at a sampling rate lower than a Nyquist sampling rate to generate the compressed data. That is, the transmitting apparatus may perform the data compression procedure performed by the data compression apparatus 100 in FIG. 2.

The receiving apparatus receives compressed data from the transmitting apparatus, equalizes the compressed data, generates domain-converted decompressed data by up-sampling the equalized compressed data, and performs an inverse-domain conversion on the domain-converted decompressed data to generate decompressed data.

Specifically, the decompressed data may have an acceptable Error Vector Magnitude (EVM). For example, if a loss generated in the data decompression procedure is not higher than 3%, the decompressed data may be regarded as a signal identical to an original signal (that is, the input data of the transmitting apparatus).

Specifically, the receiving apparatus may generate the domain-converted decompressed data by deriving an up-sampling vector which can up-sample the equalized compressed data and multiplying the equalized compressed data by the up-sampling vector. Here, the up-sampling vector may be derived as an inverse matrix of the down-sampling vector by using an L1 minimization technique. That is, the receiving apparatus may perform the data decompression procedure performed by the data decompression apparatus 200 in FIG. 3.

According to the above-described network system 300 according to an embodiment of the present invention, the transmitting apparatus may compress data to be transmitted by sampling the data at a sampling rate lower than a Nyquist sampling rate, and the receiving apparatus may decompress the compressed data. Therefore, the present invention may provide a higher compression ratio as compared with that of conventional technologies. That is, although the conventional technologies provide about 50% compression ratio, the present invention may provide a compression ratio up to 75%.

Also, embodiments of the present invention may reduce a Capital Expenditure (CAPEX) and an Operating Expenditure (OPEX) consumed for additional investments on network systems coping with explosive increases of wireless traffics.

While the example embodiments of the present invention and their advantages have been described in detail, it should be understood that various changes, substitutions and alterations may be made herein without departing from the scope of the invention.

What is claimed is:

1. A data compressing apparatus for a network interface, the apparatus comprising:
a domain converting part performing a domain conversion on input data to generate domain-converted input data; and
a data compression part generating compressed data by down-sampling the domain-converted input data at a sampling rate lower than a Nyquist sampling rate.

2. The apparatus of claim 1, wherein the domain converting part performs the domain conversion on the input data by using one of a Fast Fourier Transform (FFT), a Discrete Cosine Transform (DCT), and a Discrete Wavelet Transform (DWT).

3. The apparatus of claim 1, wherein the domain converting part calculates a sparsity value about the domain-converted input data.

4. The apparatus of claim 1, wherein the data compression part down-samples the domain-converted input data by using one of a low pass filtering, a random sampling, and a nonlinear vector function.

5. The apparatus of claim 1, wherein the data compression part processes the domain-converted input data by representing the domain-converted input data in vector format.

6. The apparatus of claim 5, wherein the data compression part multiplies the domain-converted input data by a down-sampling vector which can sample the domain-converted input data at a sampling rate lower than a Nyquist sampling rate to generate the compressed data.

7. A data decompression apparatus for a network interface, the apparatus comprising:
a channel equalization part receiving compressed data generated by down-sampling at a sampling rate lower than a Nyquist sampling rate, equalizing the compressed data in order to compensate channel distortion, and generating equalized compressed data;
a data decompression part generating domain-converted decompressed data by up-sampling the equalized compressed data; and
a domain inverse-converting part performing an inverse-domain conversion on the domain-converted decompressed data to generate decompressed data.

8. The apparatus of claim 7, wherein the data decompression part generates the domain-converted decompressed data by deriving an up-sampling vector which can up-sample the equalized compressed data and multiplying the equalized compressed data by the up-sampling vector.

9. The apparatus of claim 8, wherein the up-sampling vector is derived using an L1 minimization technique.

10. The apparatus of claim 7, wherein the domain inverse-converting part performs the domain inverse-conversion corresponding to a domain-conversion by using one of a Fast Fourier Transform (FFT), a Discrete Cosine Transform (DCT), and a Discrete Wavelet Transform (DWT).

11. A network system performing data compression and decompression, comprising:
a transmitting apparatus performing a domain conversion on input data to generate domain-converted input data, generating compressed data by down-sampling the domain-converted input data at a sampling rate lower than a Nyquist sampling rate, and transmitting the compressed data; and
a receiving apparatus receiving the compressed data, equalizing the compressed data to generate equalized compressed data, generating domain-converted decompressed data by up-sampling the equalized compressed data; and performing an inverse-domain conversion on the domain-converted decompressed data to generate decompressed data.

12. The system of claim 11, wherein the transmitting apparatus down-samples the domain-converted input data by using one of a low pass filtering, a random sampling, and a nonlinear vector function.

13. The system of claim 11, wherein the transmitting apparatus processes the domain-converted input data by representing the domain-converted input data in vector format, and multiplies the domain-converted input data by a down-sampling vector which can sample the domain-converted input data at a sampling rate lower than a Nyquist sampling rate to generate the compressed data.

14. The system of claim 11, wherein the receiving apparatus generates the domain-converted decompressed data by deriving an up-sampling vector which can up-sample the equalized compressed data and multiplying the equalized compressed data by the up-sampling vector.

15. The system of claim 14, wherein the up-sampling vector is derived using an L1 minimization technique.
